(19) United States
(12) Patent Application Publication
(10) Pub. No.: US 2008/0233703 A1
(43) Pub. Date: Sep. 25, 2008

(54) POLYSILICON CONDUCTIVITY IMPROVEMENT IN A SALICIDE PROCESS TECHNOLOGY

(75) Inventors: Romain Coppard, Rousset (FR); Jerome Lolivier, Aix En Provence (FR)

Correspondence Address: SCHWEGMAN, LUNDBERG & WOESSNER / ATMEL, P.O. BOX 2938, MINNEAPOLIS, MN, 55402, US

(73) Assignee: ATMEL CORPORATION, San Jose, CA (US)

(21) Appl. No.: 11/689,267

(22) Filed: Mar. 21, 2007

(51) Int. Cl. H01L 21/3205; H01L 21/336

(52) U.S. Cl. 438/308; 438/592; 257/E21.294; 257/E21.409

(57) ABSTRACT

An electronic device and method for forming same. The electronic device includes a source and drain region. Each region has an uppermost portion comprised of a first silicide where the first silicide is overlaid with a first dielectric layer. The electronic device further includes a gate region having an uppermost portion comprised of a second silicide. The second silicide is both thicker than the first silicide and has a lower resistivity than the first silicide with at least a portion of the second silicide being formed in an opening in the first dielectric layer.

### TECHNICAL FIELD

The present invention relates generally to a method of fabrication and a resulting semiconductor device. More specifically, the present invention relates to a salicide fabrication technology which affects only polysilicon gate regions of the semiconductor device.

### BACKGROUND ART

Low resistivity metal silicide regions are commonly formed on silicon-containing features in semiconductor fabrication processes. The silicide regions enable efficient electrical interconnection of components in an electronic device. Silicides are compound materials formed from a chemical reaction between various forms of silicon (e.g., single-crystal or polycrystalline) with a metal. Self-aligned silicides (referred to as salicides) are formed on silicon-containing features such as transistor gates and source/drain regions. Salicides provide precise placement of a layer of low resistivity material on the feature.

In a self-aligned silicide processing method, a blanket metal layer is deposited on exposed portions of silicon-containing features. The metal is then reacted with portions of the features to form silicide regions. Portions of the features that are not exposed, for example, portions covered by a spacer, do not form a silicide region. In this manner, self-aligned silicides are selectively formed on the features without patterning or etching deposited silicide to define low resistively regions. Self-aligned silicides can be formed from metals that include nickel, titanium, cobalt, as well as other metals that react with silicon to form silicides.

While the vast majority of prior art processes depend upon a two-step rapid thermal anneal (RTA) to obtain a low resistivity silicide phase, one-step RTA processes are known. The one-step RTA processes of the prior art typically employ high temperatures. With reference to FIGS. 1A-1C, a one-step RTA process of the prior art is a method of fabricating a self-aligned silicide structure. FIG. 1A includes a substrate 101, doped active regions 103A contained within the substrate 101, and a silicon-containing feature 105A. The substrate 101 is typically a silicon wafer. The silicon-containing feature 105A may be, for example, a polysilicon gate region of a transistor. The silicon-containing feature 105A has adjacent spacers 107. The adjacent spacers 107 are typically fabricated from silicon dioxide, silicon nitride, or another dielectric material. The doped active regions 103A may serve as a source and drain of the transistor.

In FIG. 1B, a layer of a silicide-forming metal 109 (or alternatively, a metal alloy) is blanket-deposited over exposed portions of the substrate 101 and the silicon-containing feature 105A. A high temperature RTA process step is applied, typically at temperatures exceeding 500° C. The high temperature RTA step causes portions of the silicide-forming metal 109 to react with exposed portions of the substrate 101 and the silicon-containing features 105A. A subsequent selective wet etch step (not shown) is required to remove any excess (i.e., unreacted metal) portions of the silicide-forming metal 109.

Referring now to FIG. 1C, after the high temperature RTA step and the subsequent selective wet etch are performed, a low resistivity metal silicide 111 is formed. A portion of the material composition of various structures has changed, thus forming silicided doped active regions 103B and a silicon-containing silicided feature 105B. Note the silicided doped active regions 103B and the silicon-containing silicided feature 105B are merely partially-consumed versions of the initial doped active regions 103A and the silicon-containing feature 105A (FIG. 1A-1B).

However, prior art silicidation steps provide little or no flexibility over resistivity levels on different components of an electronic device. For example, a desirable silicidation process would allow a lower resistivity silicide to be formed on a gate region while maintaining a thinner silicide layer over source and drain regions with an accordingly higher resistivity, thereby preventing electrical shorts in the latter regions.

Accordingly, what is needed is a method to control formation rates and thicknesses of silicides on various components of electronic devices. In transistor fabrications steps, for example, a desirous method would therefore produce a thick and eventually fully silicided gate and much thinner source and drain silicided regions.

### SUMMARY

In an exemplary embodiment, the invention is a method of forming a plurality of silicide layers on silicon-containing features of an electronic device. The method includes depositing a first metal-containing layer over each of a first and a second silicon-containing feature. A first annealing step is performed to chemically react the first metal-containing layer with each of the first and second silicon-containing features, thus forming a first and a second silicided region respectively. A protective layer is formed over the first and second silicided regions. An opening is etched in the protective layer to expose the first silicided region while continuing to mask the second silicided region. A second metal-containing layer is deposited over the first silicided region, and a second annealing step is performed to chemically react the second metal-containing layer with the first silicided region.

In another exemplary embodiment, the invention is a method of forming a plurality of silicide layers on silicon-containing features of an electronic device. The method includes depositing a first metal-containing layer over each of a first and a second silicon-containing feature, performing a first annealing step to chemically react the first metal-containing layer with each of the first and second silicon-containing features forming a first and a second silicided region respectively, forming a dielectric protective layer over the first and second silicided regions, and forming a gap-filling dielectric layer substantially covering all features on the electronic device. An opening is etched in the dielectric protective layer to expose the first silicided region while continuing to mask the second silicided region. A second metal-containing layer is deposited over the first silicided region, and a second annealing step is performed to chemically react the second metal-containing layer with the first silicided region.

In another exemplary embodiment, the invention is an electronic device. The electronic device includes a source and drain region. Each region has an uppermost portion comprised of a first silicide where the first silicide is overlaid with a first dielectric layer. The electronic device further includes a gate region having an uppermost portion comprised of a second silicide. The second silicide is both thicker than the first silicide and has a lower resistivity than the first silicide with at least a portion of the second silicide being formed in an opening in the first dielectric layer.

### BRIEF DESCRIPTION OF THE DRAWINGS

FIGS. 1A-1C are processes involved in one-step high temperature rapid thermal annealing of the prior art for fabricating a self-aligned silicided electronic device.

FIGS. 2A-2H are process steps for fabricating a self-aligned silicided electronic device in accordance with embodiments of the present invention.

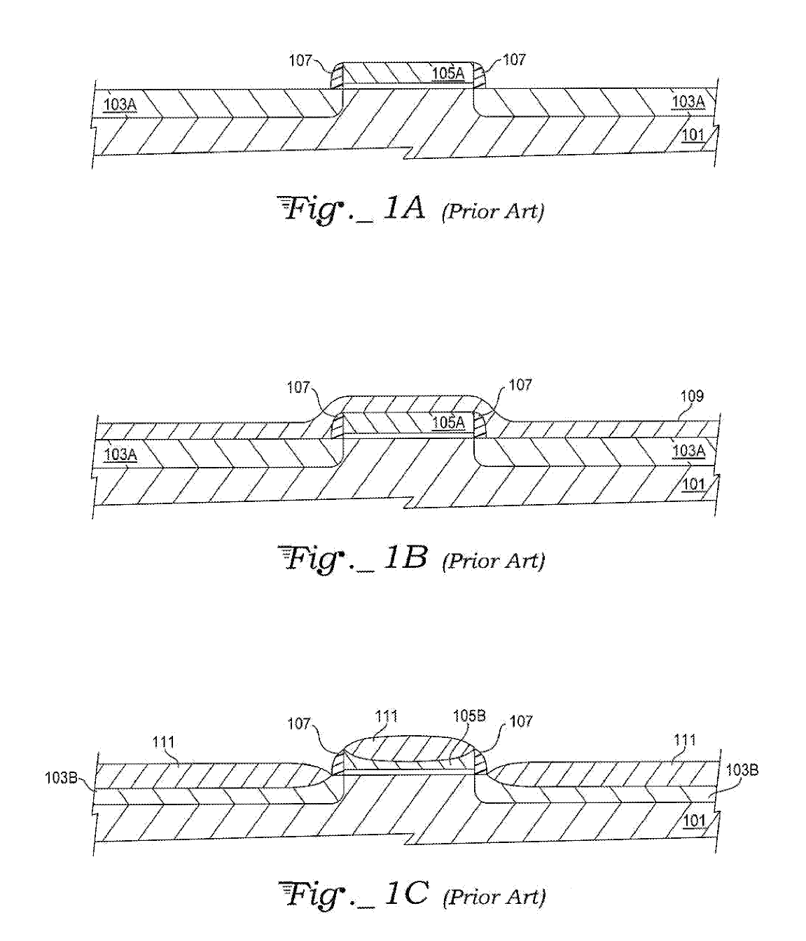

### DETAILED DESCRIPTION

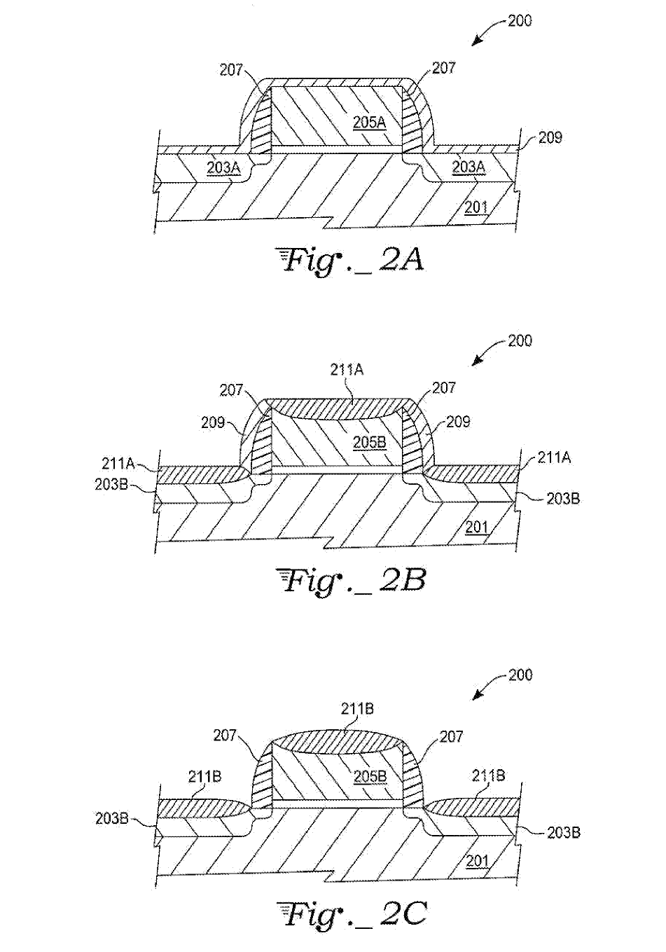

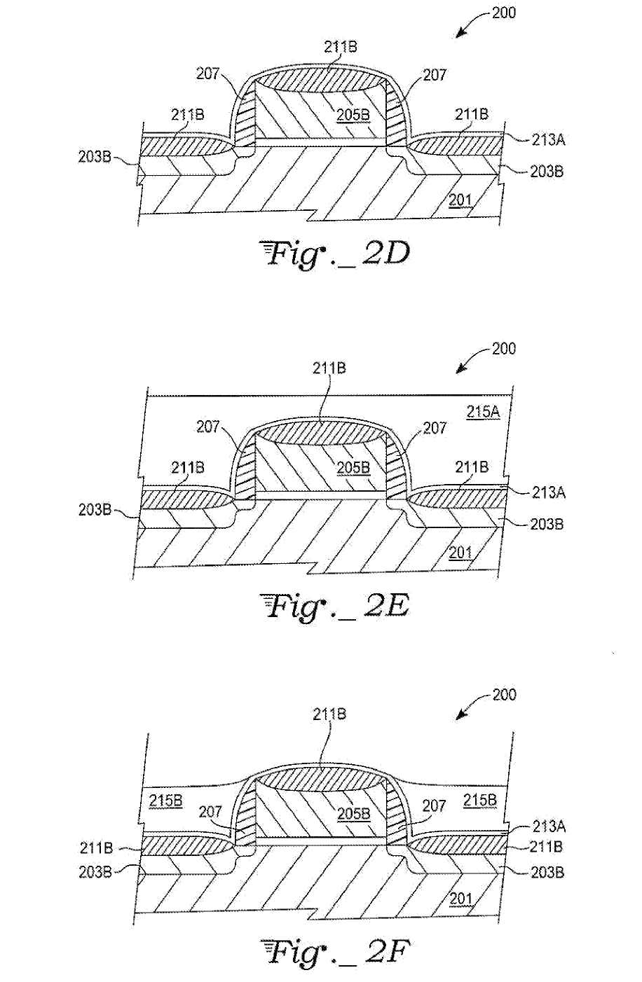

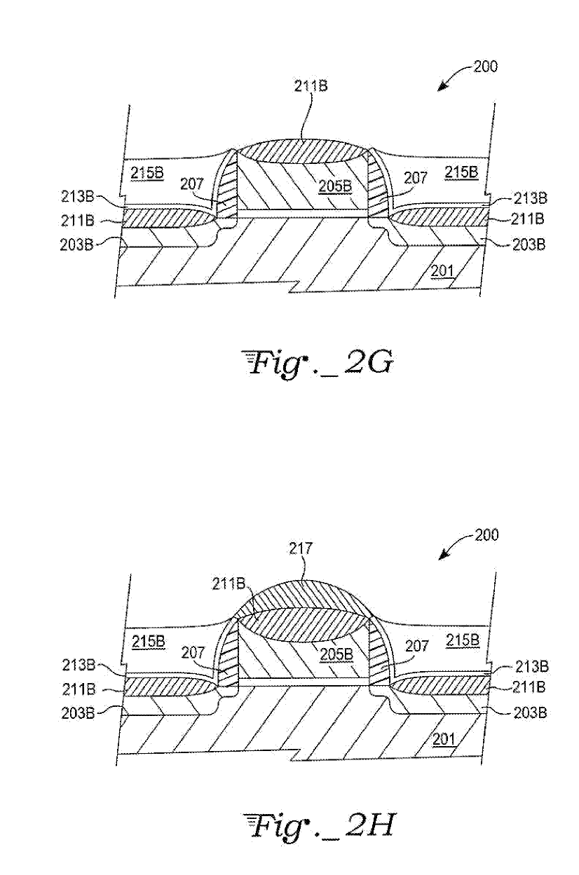

Referring to FIG. 2A, a portion of a semiconductor device 200 includes a substrate 201, one or more doped silicon-containing regions 203A, and a silicon-containing feature 205A. The portion of the semiconductor device 200 may be any portion of a typical integrated circuit. For illustrative purposes only, the semiconductor device 200 is intended to be representational only and may be considered to be, for example, a portion of a floating gate memory cell or a field-effect transistor. In the case of a floating gate memory cell, only portions of the cell are shown and the silicon-containing feature 205A could be considered to be a control gate. A skilled artisan will readily envision how various semiconductor devices would actually be fabricated in practice and how silicide processes described herein will be applicable to various types of devices.

The substrate 201 may be comprised of various materials known in the semiconductor art. Such materials include silicon (or other group IV semiconducting materials), compound semiconductors (e.g., compounds of elements, especially elements from periodic table Groups III-V and II-VI), quartz photomasks (e.g., a mask used as a device substrate with a deposited and annealed polysilicon layer or a deposited/sputtered metal layer over one surface), or other suitable materials. Frequently, the substrate 201 will be selected based upon an intended use of a finalized semiconducting product. For example, a memory cell used as a component in an integrated circuit for a computer may be formed on a silicon wafer. A memory cell used for lightweight applications or flexible circuit applications, such as a cellular telephone or personal data assistant (PDA), may form the memory cell on a polyethyleneterephthalate (PET) substrate deposited with silicon dioxide and polysilicon followed by an excimer laser annealing (ELA) anneal step. For purposes of exemplary embodiments described herein, only the doped silicon-containing regions 203A, and the silicon-containing feature 205A need be comprised at least partially of silicon. In a specific exemplary embodiment, the substrate 201 may be selected to be a silicon wafer. A preferential chemical etch or, alternatively, an in-situ sputter etch may be applied to the substrate 201 prior to any metal deposition steps.

Spacers 207 are formed along sidewalls of the silicon-containing feature 205A. Fabrication of the spacers 207 is known in the art. The spacers 207 are frequently formed from a dielectric material such as a chemical vapor deposition (CVD) deposited silicon dioxide or silicon nitride. A first blanket metal layer 209 is formed over exposed areas of the semiconductor device 200. The blanket metal layer 209 may be, for example, a nickel, cobalt, or other metal or metal alloy which chemically reacts with silicon to form a silicide. In a specific exemplary embodiment, the blanket metal layer 209 is a cobalt layer sputtered over the semiconductor device 200. (In contrast, prior art techniques frequently require metal layer such as Co or Ni to be capped with a barrier layer such as titanium nitride (TiN). The blanket metal layer 209 is formed to a thickness of between 1 nm and 100 nm but may vary depending upon device type, design rules, and other factors. A required thickness may be readily determined by a skilled artisan.

In FIG. 2B, a rapid thermal anneal (RTA) step is applied to the semiconductor device 200. In a case where the specific exemplary embodiment of the blanket metal layer 209 (FIG. 2A) is comprised of cobalt, the RTA step forms a cobalt silicide (CoSi₂) layer 211A.

In a specific exemplary embodiment, the RTA step is performed at between 250° C. to 350° C. for nickel silicide. Cobalt and titanium may require higher temperatures. The RTA step produces partially-consumed doped silicon-containing feature 205B. (The exemplary CoSi₂ layer 211A is formed by a chemical reaction between the cobalt and underlying silicon of the partially-consumed underlying silicon-containing regions 203B or the silicon-containing feature 205B.) In other specific exemplary embodiments, temperatures as high as 750° C. or more may be employed.

referring now to FIG. 2C, a selective etchant is used to remove any excess amounts of the blanket metal layer 211A, thus forming a stabilized silicide film 211B. The stabilized silicide film 211B may serve as a low resistivity contact layer for subsequent fabrication steps.

In FIG. 2D, a dielectric protective (or masking) layer 213A is deposited or otherwise formed over exposed portions of the semiconductor device 200. In a specific exemplary embodiment, the dielectric protective layer 213A is a 100 Å to 1000 Å thick silicon nitride (Si₃N₄) or oxynitride film deposited by plasma-enhanced chemical vapor deposition (PECVD). A gap-fill dielectric deposition 215A (FIG. 2E) is then formed over the dielectric protective layer 213A. In a specific embodiment, the gap-fill dielectric deposition 215A is a 6000 Å thick high temperature undoped silicate glass (HT USG) deposition. However, a skilled artisan will recognize that other materials and deposition techniques may be used. Also, a final thickness of the gap-fill dielectric deposition 215A will at least partially depend upon a height of the underlying partially-consumed silicon-containing feature 205B. Generally, the gap-fill dielectric deposition 215A will substantially cover all features on the semiconductor device 200. A chemical (e.g., a wet etch or plasma etch) and/or mechanical etching step is performed to expose an uppermost portion of the dielectric protective layer 213A (FIG. 2F) and form a planarized gap-fill dielectric deposition 215B. After the etch step, an uppermost surface of the planarized gap-fill dielectric deposition 215B and the uppermost portion of the dielectric protective layer 213A are substantially coplanar.

The etching step may be accomplished by, for example, an optional chemical mechanical planarization (CMP) step. In a case where the gap-fill dielectric deposition 215A is an oxide (such as the HT USG), the CMP step may optionally be followed by either a dry or wet light oxide etch back step. Such etch back steps are known in the art. For example, the dry etch may be an anisotropic dry etch such as a reactive-ion etch (RIE). The wet etch may be an isotropic wet chemical etch.

With reference to FIG. 2G, a high-selectivity (i.e., selectively etching silicon nitride at a higher rate than either silicon dioxide or silicide) wet or dry chemical etch removes exposed portions of the dielectric protective layer 213A, stopping on the underlying stabilized silicide film 211B. The high-selectivity etchant could be, for example, either a wet etchant such as orthophosphoric acid (H₃PO₄) or a plasma etch. The high-selectivity etch leaves the planarized gap-fill dielectric deposition 215B as a dielectric protective layer, uncovers the stabilized silicide film 211B, and forms an etched dielectric protective layer 213B.

Referring now to FIG. 2H, a second silicidation step occurs by depositing a second metal layer (not shown) over exposed portions of the stabilized silicide film 211B through the planarized gap-fill dielectric deposition 215B. The second metal layer may be chosen to be the same metal or metal alloy used in the first blanket metal layer 209 (FIG. 2A). Alternatively, the second metal layer may be chosen to contain a metal dissimilar to the first blanket metal layer 209. In a specific embodiment, the second metal layer is chosen to be cobalt. Thus, after an additional RTA step and selective etch of any unreacted metal, the second metal layer forms an additional silicide layer 217. The combination of the stabilized silicide film 211B and the additional silicide layer 217 together form a thick, low resistivity silicidation layer over the underlying partially-consumed silicon-containing feature 205B. In a specific embodiment, the additional silicide layer 217 may be a CoSi₂ layer where the second metal layer is deposited to a depth of about 200 Å. In other exemplary embodiments, this range may be from 100 Å to 1000 Å.

Significantly, due to the masking effects of the etched dielectric protective layer 213B and the planarized gap-fill dielectric deposition 215B, the underlying stabilized silicide film 211B is either not affected or merely minimally affected by subsequent metal depositions or additional anneal steps. Therefore, a low resistivity area may be formed over, for example, a gate region while having little or no affect on the source and drain regions.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that in accordance with the present invention, the thick fully silicided metal gate and the thinner silicided source and drain regions can be composed of the same or different metal silicide such as, for example, silicides of titanium (Ti), tantalum (Ta), tungsten (W), nickel (Ni), platinum (Pt), palladium (Pd), and alloys thereof. Of the various silicides, silicides of Co, Ni, or Pt, in their lowest resistivity phase, are particularly advantageous. Alternatively, in other embodiments, the source and drain regions may include CoSi₂, while the silicided metal gate includes CoSi₂ and nickel monosilicide (NiSi). A person of ordinary skill in the art may readily envision permutations and combinations of other alloys that are all within a scope of the present invention. Further, different dielectric, protective, or masking materials may be used as well as different deposition, sputtering, and forming techniques may be employed. Although specific mention is made of transistor gates and source/drain regions, the invention may be applied to numerous other silicon-containing device types as well. The specification and drawings are, accordingly, to be regarded in an illustrative rather than a restrictive sense.

What is claimed is:

1. A method of forming a plurality of silicide layers on silicon-containing features of an electronic device, the method comprising:
depositing a first metal-containing layer over each of a first and a second silicon-containing feature;
performing a first annealing step to chemically react the first metal-containing layer with each of the first and second silicon-containing features forming a first and a second silicided region respectively;
forming a protective layer over the first and second silicided regions;
etching an opening in the protective layer to expose the first silicided region while continuing to mask the second silicided region;
depositing a second metal-containing layer over the first silicided region; and
performing a second annealing step to chemically react the second metal-containing layer with the first silicided region.

2. The method of claim 1 wherein each of the first and second metal-containing layers is selected to be an elemental metallic material.

3. The method of claim 1 wherein each of the first and second meal-containing layers is selected to be a compound metallic material.

4. The method of claim 1 wherein the first silicon-containing feature is fabricated to form a transistor gate region.

5. The method of claim 1 wherein the second silicon-containing feature is fabricated to form a transistor source/drain region.

6. The method of claim 1 wherein at least one of the metal-containing layers is selected to include cobalt.

7. The method of claim 1 wherein at least one of the metal-containing layers is selected to include nickel.

8. The method of claim 1 wherein the protective layer is selected to be a dielectric material.

9. A method of forming a plurality of silicide layers on silicon-containing features of an electronic device, the method comprising:
depositing a first metal-containing layer over each of a first and a second silicon-containing feature;
performing a first annealing step to chemically react the first metal-containing layer with each of the first and second silicon-containing features forming a first and a second silicided region respectively;
forming a dielectric protective layer over the first and second silicided regions;
forming a gap-filling dielectric layer substantially covering all features on the electronic device,
etching an opening in the dielectric protective layer to expose the first silicided region while continuing to mask the second silicided region;
depositing a second metal-containing layer over the first silicided region; and
performing a second annealing step to chemically react the second metal-containing layer with the first silicided region.

10. The method of claim 9 further comprising:
planarizing the gap-filling dielectric layer such that it is substantially coplanar with an uppermost portion of the protective layer prior to etching the opening.

11. The method of claim 9 wherein each of the first and second metal-containing layers is selected to be an elemental metallic material.

12. The method of claim 9 wherein each of the first and second metal-containing layers is selected to be a compound metallic material.

13. The method of claim 9 wherein the first silicon-containing feature is fabricated to form a transistor gate region.

14. The method of claim 9 wherein the second silicon-containing feature is fabricated to form a transistor source/drain region.

15. The method of claim 9 wherein at least one of the metal-containing layers is selected to include cobalt.

16. The method of claim 9 wherein at least one of the metal-containing layers is selected to include nickel.

17. An electronic device comprising:
a source and drain region, each region having an uppermost portion comprised of a first silicide, the first silicide being overlaid with a first dielectric layer; and
a gate region having an uppermost portion comprised of a second silicide, the second silicide being both thicker than the first silicide and having a lower resistivity than the first silicide, at least a portion of the second silicide being formed in an opening in the first dielectric layer.

18. The electronic device of claim 17 further comprising a planarized second dielectric layer, the planarized second dielectric layer being substantially coplanar with an uppermost surface of a portion of the first dielectric layer.

19. The electronic device of claim 17 wherein the first and second silicides are each comprised partially of cobalt.

20. The electronic device of claim 17 wherein the first and second silicides are each comprised partially of nickel.
